(19) United States
(12) Patent Application Publication
(10) Pub. No.: US 2018/0375373 A1
(43) Pub. Date: Dec. 27, 2018

(54) IMPACT INCREMENTS-BASED STATE ENUMERATION RELIABILITY ASSESSMENT APPROACH AND DEVICE THEREOF

(71) Applicant: Tianjin University, Tianjin (CN)

(72) Inventors: Hongjie JIA, Tianjin (CN); Kai HOU, Tianjin (CN); Yunfei MU, Tianjin (CN); Xiaodan Yu, Tianjin (CN)

(73) Assignee: Tianjin University, Tianjin (CN)

(21) Appl. No.: 15/747,522

(22) PCT Filed: Aug. 28, 2015
(86) PCT No.: PCT/CN2015/088389

§ 371 Date: Jan. 25, 2018

(30) Foreign Application Priority Data
Jul. 28, 2015 (CN) 201510456039.9

(51) Int. Cl. H02J 13/00; G01R 31/40

(52) U.S. Cl. CPC H02J 13/0006; G01R 31/40

(57) ABSTRACT

The present invention discloses an impact increments-based state enumeration (IISE) reliability assessment approach and device thereof. The method includes: inspecting the accessibility of all elements of the independent adjacency matrix by the breadth-first search method; if there is inaccessible element, the impact increment is zero and the power system state is reselected; if there is no inaccessible element, evaluating the impact of the power system state under all load levels via optimal power flow algorithm, acquiring the impact expectations of power system state under different load levels, and then acquiring the impact increments of the power system state; acquiring the reliability index of power system by impact increment when all the centralized power system states have been analyzed and the maximum number of contingency order has reached. The device of the present invention includes: inspection module (1), first acquisition module (2) and second acquisition module (3), which realizes the reliability indices calculation via these modules. The invention improves the precision and efficiency of calculation and reduces the computational complexity.

### TECHNICAL FIELD

The present invention relates to the field of reliability assessment of power system, especially relates to an impact increments-based state enumeration (hereinafter referred to as IISE) reliability assessment approach and device thereof.

### BACKGROUND OF THE PRESENT INVENTION

In general, there are two elementary reliability assessment approaches: the Monde Carlo simulation method (MCS) and the state enumeration (SE) method.

The state enumeration method enumerates all possible states of power system to calculate their impacts and probabilities until a certain failure order or a given probability threshold is reached. In practical applications, the SE technique is more efficient for small scale systems rather than large scale systems or low reliability systems, since the number of system states increases exponentially with the equipment number. For the large-scale system or high unavailability equipments, high order contingencies were not well considered in those techniques, and the obtained reliability indices were lower bound estimations instead of true values. Therefore, due to its clear physical concept and high precision of the model, the state enumeration technique is suitable for power systems with small scale, simple structure and low unavailability of equipments.

The basic idea of the Monde Carlo simulation method is to randomly sample individual elements states inside the system and update reliability indices until a stopping criterion is satisfied. This method can be further classified into two basic categories according to different sampling principles: the nonsequential MCS (NMCS) and the sequential MCS (SMCS). The MCS has a major advantage that the calculation efficiency thereof is almost unaffected by the system scale, thus it is suitable for large scale systems. However, the MCS becomes remarkably time consuming when applying to high reliability systems (equipments are less likely to fail). This is because abnormal system states are increasingly difficult to be sampled when the system reliability is improved. Therefore, the Monde Carlo simulation method is suitable for power systems with large scale or low reliability.

The Monde Carlo simulation method and the state enumeration technique have their own advantages and offer complementary applicable situations. Therefore, by combining the merits of the MCS and the SE, a hybrid reliability assessment approach was proposed. The hybrid method adopts state enumeration technique in the case of analytical method, and adopts Monte Carlo method in situations that exceed the applicable scope of the analytical method. And in the application of Monte Carlo method, the information provided by the state enumeration technique can be used to reduce computation time and improve the accuracy of calculation.

However, the existing methods are unable to meet the requirements of online application for computational efficiency and precision. To achieve the real-time application of the power system reliability assessment, there is an urgent need for a higher efficiency and better accuracy evaluation method.

### SUMMARY OF THE PRESENT INVENTION

The present invention discloses an impact increments-based state enumeration (IISE) reliability assessment approach and device thereof, which improves the accuracy and efficiency of calculation and reduces the complexity of the calculation. The details are described below:

An impact increments-based state enumeration (IISE) reliability assessment approach, including the following steps:

Inspecting the accessibility of all elements of the independent adjacency matrix by the breadth-first search method; if there is inaccessible element, the impact increment is zero and the power system state is reselected;

If there is no inaccessible element, evaluating the impact of the power system state under all load levels via optimal power flow algorithm, acquiring the impact expectations of power system state under different load levels, and then acquiring the impact increments of the power system state;

Acquiring the reliability index of power system by impact increment when all the centralized power system states have been analyzed and the maximum number of contingency order has reached.

Wherein, before the step of accessibility” inspecting the accessibility of all elements of the independent adjacency matrix by the breadth-first search method”, an impact increments-based state enumeration (IISE) reliability assessment approach also includes:

Calculating the sensitivity of each equipment impedance to each branch power flow by perturbation method, and determining the independence of each equipment according to the sensitivity;

Selecting a power system state from a state set, and creating the independent adjacency matrix of the power system state;

Wherein, the method also comprises: inputting power system data, equipment reliability data and preset parameters, and initializing the order of contingency.

Further, the preset parameters include the maximum contingency search order and the sensitivity threshold of equipment independence.

Wherein, the step of “determining the independence of each equipment according to the sensitivity” further comprises the following steps:

If there exists a branch, which makes the sensitivity index of branch flow distribution to the impedance of each faulty device is greater than the independence sensitivity threshold of the device, the two equipments are dependent.

An impact increments-based state enumeration (IISE) reliability assessment device comprises:

Inspection module: inspecting the accessibility of all elements of the independent adjacency matrix corresponding to the selected power system state by the breadth-first search method; if there is inaccessible element, the impact increment of the selected power system state is zero and the power system state is reselected;

First acquisition module: if there is no inaccessible elements, evaluating the impact of the power system state under all load levels via optimal power flow algorithm, acquiring the impact expectations of power system state under different load levels, and then acquiring the impact increments of the power system state;

Second acquisition module: acquiring the reliability index of the power system by impact increment when all the centralized power system states have been analyzed and the maximum number of contingency order has been reached.

The device of the present invention also includes:

Third acquisition module: acquiring the sensitivity of each equipment impedance to the power flow of each branch through the perturbation method;

Determining module: determining the independence among equipments according to the sensitivity;

Creating module: selecting a power system state from the state set and creating an independent adjacency matrix of the power system state through the independence among the equipments.

The device of the present invention also includes:

Inputting and initializing module: inputting power system data, equipment reliability data and preset parameters, and initialize the order of contingency.

Further, the preset parameters of the device include the maximum contingency search order and the sensitivity threshold of equipment independence.

Further, the determining module includes:

Determining sub-module: if there exists a branch, which makes the sensitivity index of branch flow distribution to the impedance of each faulty device is greater than the independence sensitivity threshold of the device, the two components are dependent.

The technical scheme of the present invention has the advantages of: the core of this invention is to replace the system impact with the impact increment, which can effectively promote the proportion of the lower order states in reliability indices; adopting only a few lower order states to calculate the more accurate reliability index. Furthermore, the present invention proves that the impact increment of higher order contingency can be ignored when calculating the reliability index, which greatly improves the computational efficiency.

### BRIEF DESCRIPTION OF THE DRAWINGS

FIG. 1 is a flow chat of the impact increments-based state enumeration (IISE) reliability assessment approach;

FIG. 2 is a schematic diagram of the impact increments-based state enumeration (IISE) reliability assessment device;

FIG. 3 is another flow chat of the impact increments-based state enumeration (IISE) reliability assessment device;

FIG. 4 is another flow chat of the impact increments-based state enumeration (IISE) reliability assessment device;

FIG. 5 is a schematic diagram of determination module;

FIG. 6 is a topological structure diagram of IEEE 118-bus system;

FIG. 7a is a comparison diagram of the EENS indices convergence curves when applied the present invention, the state enumeration method and the Monte Carlo method to IEEE 118-bus system;

FIG. 7b is a comparison diagram of the PLC indices convergence curves when applied the present invention, the state enumeration method and the Monte Carlo method to IEEE 118-bus system;

FIG. 8a is a comparison diagram of the EENS indices convergence curves of the relative errors of the reliability indices when applied the present invention, the state enumeration method and the Monte Carlo method to IEEE 118-bus system;

FIG. 8b is a comparison diagram of the PLC indices convergence curves of the relative errors of the reliability indices when applied the present invention, the state enumeration method and the Monte Carlo method to IEEE 118-bus system;

FIG. 9a is a comparison diagram of the EENS indices convergence curves when applied the present invention, the state enumeration method and the Monte Carlo method to PEGASE 1354-bus system;

FIG. 9b is a comparison diagram of the PLC indices convergence curves when applied the present invention, the state enumeration method and the Monte Carlo method to PEGASE 1354-bus system;

FIG. 10a is a comparison diagram of the EENS indices convergence curves of the relative errors of the reliability indices when applied the present invention, the state enumeration method and the Monte Carlo method to PEGASE 1354-bus system;

FIG. 10b is a comparison diagram of the PLC indices convergence curves of the relative errors of the reliability indices when applied the present invention, the state enumeration method and the Monte Carlo method to PEGASE 1354-bus system;

In which:

| | |
|---|---|
| 1: Inspection module; | 2: First acquisition module; |
| 3: Second acquisition module; | 4: Third acquisition module; |
| 5: Determination module; | 6: Creation module; |
| 7: Input and initialization module | 51: Determination submodule. |

### DETAILED DESCRIPTION OF THE PRESENT INVENTION

In order to make the objective, technical scheme and advantages of the present invention more clear, the present invention will be further described below.

### Embodiment 1

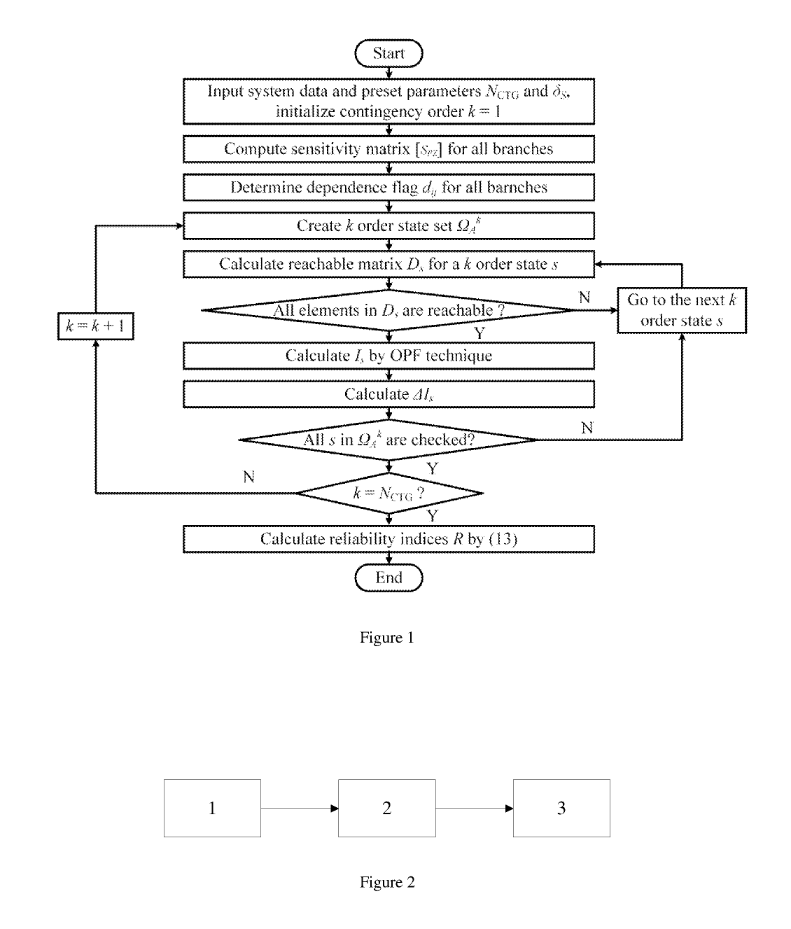

As shown in FIG. 1, the impact increments-based state enumeration (IISE) reliability assessment approach in this embodiment includes the following steps:

101: Inputting power system data, equipment reliability data and preset parameters, and initializing the order of contingency k=1.

102: Calculating the sensitivity value S_{PZ} of each equipment impedance to each branch power flow by perturbation method, and determining the independence of each equipment according to S_{PZ};

103: Selecting a power system state s from k-order state set Ω_{A}^{k}, and creating the independent adjacency matrix Dₛ of the power system state s;

104: Inspecting the accessibility of all the elements of the independent adjacency matrix Dₛ by the breadth-first search method; If there is inaccessible element, dividing the failure equipments of power system state s into at least two independent subsets, and go to step 103; Otherwise, go to step 105;

105: Evaluating the system impacts I_{s,l} of system state s of all the load levels by optimal power flow (OPF) algorithm and calculating the impact expectations;

Based on the impact function, the following corresponding reliability index can be obtained:

(1)EENS (expected energy not supplied, MWh/yr)

When the impact function I is the annual load loss (MWh/yr), the obtained reliability indices is EENS.

(2)PLC (probability of load curtailments)

When the impact function I is the flag of load loss, the obtained reliability indices is PLC.

106: Calculating the impact increment ΔIₛ of power system state s; inspecting whether all the system states in the k-order contingency set Ω_{A}^{k} have been analyzed, if so, go to step 107; Otherwise, go to step 103;

107: If k=N_{CTG}(The maximum contingency search order), go to step 108; Otherwise, k=k+1 and go to step 103;

108: Calculating the reliability index of power system.

By the above Steps from 101 to 108, the accuracy and efficiency are improved, which reduces the complexity of the calculation.

### Embodiment 2

The technical scheme of the embodiment 1 will be further described with following formulas, as follows:

201: Inputting power system data, equipment reliability data and preset parameters, and initializing the order of contingency k=1;

Wherein, power system data comprise: power system node, branch, generator parameters, load level of each node, annual load curve, etc; equipment reliability data comprise: the unavailability of node, branch and generator; preset parameters comprise: the maximum contingency search order N_{CTG} and the sensitivity threshold of equipment independence δₛ.

202: Calculating the sensitivity S_{PZ} of each branch (including line and transformer);

203: Determining the independence of each equipment according to S_{PZ};

If branch i and j are dependent, dᵢⱼ=1; otherwise, dᵢⱼ=0.

204: Creating the k order contingency state set Ω_{A}^{k}:

Ω_{A}^{k}={s|s⊂A,Card(s)=k} (1)

Wherein, A is the set of all equipments in the power system; s is a system state, which is denoted by a set of all failure equipments corresponding to it; Card(s) represents the contingency order of state s.

205: Picking a system state s in Ω_{A}^{k} and creating the adjacency matrix Dₛ for s:

Dₛ=[dᵢⱼ], i,j∈s (2)

206: Based on the achieved Ds, inspecting the accessibility of all elements in Ds by using the breadth first search technique;

As used herein, the term “accessibility” refers to the ability to get from one node V₁ to another node V₂ within an undirected connected graph determined by the adjacency matrix Dₛ.

If any two nodes are unreachable in the unconnected graph, the faulty device in the power system state s can be divided into at least two mutually independent subsets, and the impact increment ΔIₛ thereof is 0, then the calculation can be omitted, and go to step 205. Otherwise, if all nodes are reachable to each other, go to step 207.

207: Evaluating the system impact I_{s,l} under each load level l by OPF algorithm:

$${I}_{s} = E ( {I}_{s , l} ) = {\sum }_{l = 1}^{{n}_{l}} {I}_{s , l} {P}_{l} \qquad ( 3 )$$

Wherein, Pₗ is the probability of load level l; nₗ is the total number of load levels.

208: Calculating the impact increment ΔIₛ of the power system state s:

$$Δ {I}_{s} = {I}_{s} - {\sum }_{k = 1}^{{n}_{s}} {\sum }_{u ∈ {Ω}_{s}^{k}} Δ {I}_{u} \qquad ( 4 )$$

Wherein, nₛ is the failure equipment number of the power system state s; Ωₛ^{k} is the k order subset of the system state s; u is a element of Ωₛ^{k}; ΔIᵤ is the load loss increment of u.

Ωₛ^{k} is determined by:

Ωₛ^{k}={s₁|s₁⊂s,Card(s₁)=k} (5)

Wherein, ⊂ is the subset symbol and s₁ is a subset of power system state s; Card(s₁) represents the cardinality of state s₁.

209: Determining whether all states in Ω_{A}^{k} have been analyzed, if so, go to Step 210; otherwise, go back to Step 205;

210: If k=N_{CTG}, go to Step 211; otherwise, set k=k+1 and go back to Step 204;

211: Calculating reliability indices by the following formula:

$$R = {\sum }_{k = 1}^{N} {\sum }_{s ∈ {Ω}_{A}^{k}} ( {Π}_{i ∈ s} {P}_{i} ) Δ {I}_{s} \qquad ( 6 )$$

Wherein, R is the reliability indices; Pᵢ is the unavailability of equipment i; N is the total number of system equipment.

Wherein, the sensitivity S_{PZ} in Step 202 can be calculated as follows:

In the power system, the equipment failure can be regarded as the equipment impedance is suddenly ranks from the rating value to infinity. And the equipment failure has a direct impact on the power flow distribution. Therefore, the fault equipment and the branches can be described by the sensitivity of the equipment impedance to the power flow of branches. The present invention sets the sensitivity as S_{PZ}, and adopts perturbation method to obtain the sensitivity index. The computation process of sensitivity is known to the people skilled in the art, thus no further detailed description is discussed in this embodiment case.

The independence flag dᵢⱼ among failure equipments in Step 203 can be calculated by:

The independence flag of failure equipments i and j is set as dᵢⱼ. When the following condition is satisfied, the equipments i and j are regarded as dependent, that is, dᵢⱼ=1; Otherwise, they are regarded as independent, that is, dᵢⱼ=0.

There is h∈A so that:

|S_{PZ}(h,i)|>δₛ and |S_{PZ}(h,j)|>δₛ (7)

Wherein, δₛ is the sensitivity threshold of preset parameter of equipment independence; A is the set of all equipments; S_{PZ}(h,i) is the sensitivity of power flow of branch i with respect to impedance of branch h; S_{PZ}(h,j) is the sensitivity of power flow of branch j with respect to impedance of branch.

If there is no reachable element in the independent adjacency matrix Dₛ in Step 206, the failure equipments of power system state s can be divided into at least two independent subsets, and then the impact increment ΔIₛ is 0. The basic proof process is presented as follows:

Assumption I: In the power system, it is assumed that for a higher order system state s (s is regarded as a high order state if its order is greater than or equal to 2), if its independent adjacency matrix Dₛ has any unreachable node, it is proved that there are at least two independent sets of faulty equipments in the state s. Therefore, the faulty equipments in the power system state s can be divided into at least two mutually independent subsets s₁ and s₂.

Mathematical induction method can be used to prove ΔIₛ=0 under this assumption.

First of all, for a second order system state s={i1, i2}, wherein i₁ and i₂ are fault equipments, if the assumption is satisfied, then it is obvious that ΔIₛ=Iₛ−I_{{i}_{₁}_{}}−I_{{i}_{₂}_{}}=0. Therefore, the statement ΔIₛ=0 holds for nₛ=2. Assuming that the statement ΔIₛ=0 holds for 2<nₛ<k, then for a nₛ=(k+1) order contingency state s, this statement can also be obtained. By mathematical induction, the statement holds for all high order contingency state s.

The reliability indices in power system in Step 211 can be obtained as follow:

In power system, reliability indices can be described as

$$R = {\sum }_{s ∈ Ω} I ( s ) P ( s ) \qquad ( 8 )$$

Wherein, Ω is the set of all possible system states, I(s) is the impact function of system state s, P(s) is the probability of system state s.

Assumed a power system comprises n equipments, Pᵢ and P̅ᵢ̅ are the failure and success probabilities of equipment i respectively. Iₛ is the impact of system state s. I_{ϕ} represents the impact of normal system state, and the relation is as follows:

P̅ᵢ̅=1−Pᵢ (9)

Considering a power system comprises two equipments, the reliability indices R is a polynomial with four terms, corresponding to a normal state and three contingency states, the relation is as follows:

R₂=P̅₁̅P̅₂̅I_{ϕ}+P₁P̅₂̅I₁+P̅₁̅P₂I₂+P₁P₂I₁₂ (10)

This formula can be simplified after applying formula (9):

$$\begin{matrix}{R}_{2} = {\overline{P}}_{1} {\overline{P}}_{2} {I}_{φ} + {P}_{1} {\overline{P}}_{2} {I}_{1} + {\overline{P}}_{1} {P}_{2} {I}_{2} + {P}_{1} {P}_{2} {I}_{12} \\ = ( 1 - {P}_{1} ) ( 1 - {P}_{2} ) {I}_{φ} + {P}_{1} ( 1 - {P}_{2} ) {I}_{1} + ( 1 - {P}_{1} ) {P}_{2} {I}_{2} + {P}_{1} {P}_{2} {I}_{12} \\ = {I}_{φ} - {P}_{1} {I}_{φ} - {P}_{2} {I}_{φ} + {P}_{1} {P}_{2} {I}_{φ} + {P}_{1} {I}_{1} - {P}_{1} {P}_{2} {I}_{1} + {P}_{2} {I}_{2} - {P}_{1} {P}_{2} {I}_{2} + {P}_{1} {P}_{2} {I}_{12} \\ = {P}_{1} {P}_{2} ( {I}_{12} - {I}_{1} - {I}_{2} + {I}_{φ} ) + {P}_{1} ( {I}_{1} - {I}_{φ} ) + {P}_{2} ( {I}_{2} - {I}_{φ} ) + {I}_{φ}\end{matrix} \qquad ( 11 )$$

By formula derivation, reliability indices formula can be described as a form based on the impact increments. This form has eliminated all success probability, and state impacts Is are replaced by their increments. Wherein, the impact increment ΔIₛ of the high order contingency state can be described by the formula), and the formula (11) can be further simplified as

R₂=I_{ϕ}+P₁ΔI₁+P₂ΔI₂+P₁P₂ΔI₁₂ (12)

It can be seen that impact increments of all high order contingency states are eliminated with only first order contingency states left. This implies that the main idea of the impact increments-based formula is to approximate mutually independent high order contingency states by low order ones. Thus, the impacts of system states are replaced by impact increments, the effect of low order contingency states in formula (10) is remarkably magnified, and more accurate results can be achieved without calculating impacts of numerous mutually independent high order contingency states.

Extending formula (12) to an N equipments system to achieve formula (6). Mathematical proof is shown as follows:

It is shown in formula (12) that the formula (6) holds for N=2. Assuming that formula (6) holds for N=n, then it should also hold for N=n+1, then proof completed.

Add a new equipment into the original power system having n equipments, then the system order is n+1. Therefore, reliability index Rₙ₊₁ of the new system can be deduced from Rₙ, which is the reliability index of the original power system having n equipments.

$${R}_{n + 1} = \overline{{P}_{n + 1}} {R}_{n} + {P}_{n + 1} [ {\sum }_{{k}^{′} = 0}^{N} {\sum }_{s ∈ {Ω}_{A}^{k}} ( {Π}_{i ∈ s} {P}_{i} ) ( {\sum }_{{k}_{1} = 0}^{{n}_{s}} {( - 1 )}^{{n}_{s} - {k}_{1}} {\sum }_{u ∈ {Ω}_{s}^{{k}_{1}}} {I}_{u ⋃ \{ n + 1 \}} ) ] \qquad ( 13 )$$

Wherein, {n+1} denotes the system state that only the newly added equipment is failed; Pₙ₊₁, P̅ₙ̅₊̅₁̅ are the available rate and unavailable rate for the newly added equipment, respectively. k′, k₁ represents the order of contingency states and are vary from 0; Ωₛ^{k1} is the k₁ order subset of system state s, which is determined by formula (5). u represents the cardinality of a subset Ωₛ^{k1}. Then formula (13) can be simplified into:

$$\begin{matrix}{R}_{n + 1} = {R}_{n} + {P}_{n + 1} \{ {\sum }_{{k}^{′} = 0}^{N} {\sum }_{s ∈ {Ω}_{A}^{k}} ( {Π}_{i ∈ s} {P}_{i} ) ( {\sum }_{{k}_{2} = 0}^{{n}_{s} - 1} {( - 1 )}^{{n}_{s} - {k}_{2} + 1} {\sum }_{u ∈ {Ω}_{s ⋃ \{ n + 1 \}}^{{k}_{2}}} {I}_{u} ) \} \\ = {\sum }_{k = 1}^{N + 1} {\sum }_{s ∈ {Ω}_{A ⋃ \{ n + 1 \}}^{k}} ( {Π}_{i ∈ s} {P}_{i} ) Δ {I}_{s}\end{matrix} \qquad ( 14 )$$

Wherein, k₂ represents the order of contingency states, Ωₛ^{k2} is the k₂ order subset of system state s, which is determined by the formula (5).

Thereby showing that formula (6) holds for N=n+1. By mathematical induction, formula (6) holds for all N>2.

The impact increment ΔIₛ can be obtained according to formula (4). The reliability index can be calculated by using formula (6). Different reliability index can be achieved based on different impact function Iₛ.

By performing the step 201 to step 211, the method improves the precision and efficiency when calculating the reliability index and decreases the complexity of the reliability index.

### Embodiment 3

As shown in FIG. 2, an impact increments-based state enumeration reliability assessment device, includes:

Inspection module 1: inspecting the accessibility of all elements of the independent adjacency matrix corresponding to the selected power system state through the breadth first search technique. If there is inaccessible elements, the impact increment of the selected power system state is zero and the power system state is reselected.

First acquisition module 2: if there is no inaccessible elements, evaluating the impact of the power system state under all load levels via optimal power flow algorithm, acquiring the impact expectations of power system state under different load levels, and then acquiring the impact increments of the power system state;

Second acquisition module 3: acquiring the reliability index of the power system by impact increment when all the centralized power system states have been analyzed and the maximum number of contingency order has been reached.

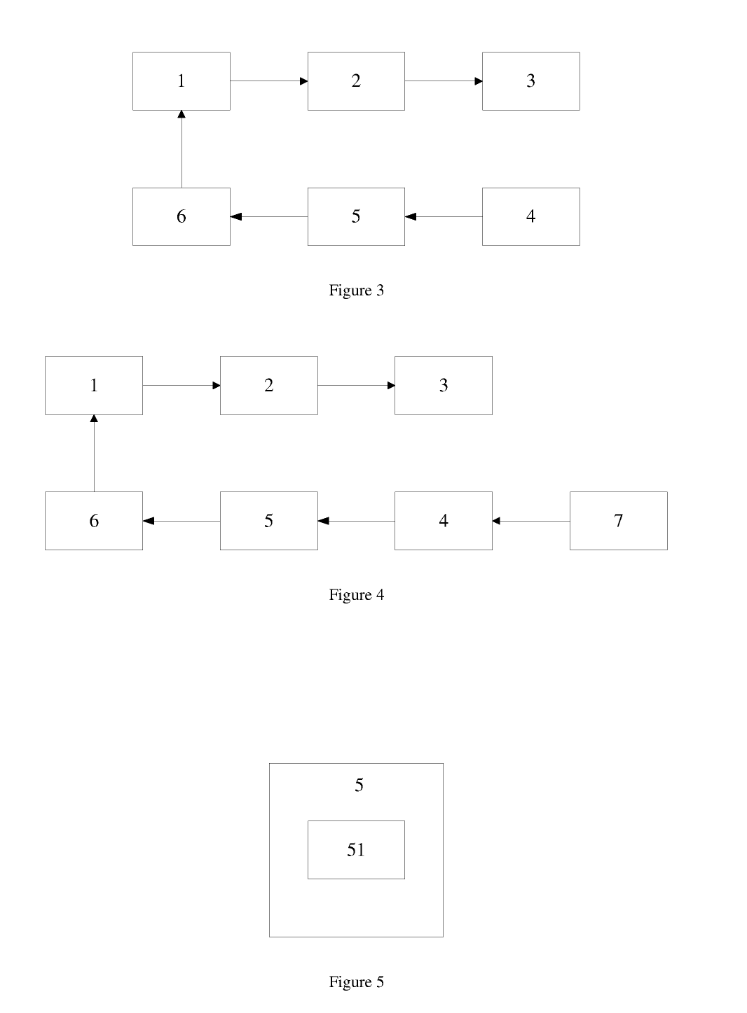

Besides, as shown in FIG. 3, the device also includes:

Third acquisition module 4: acquiring the sensitivity of each equipment impedance to the power flow of each branch through the perturbation method;

Determining module 5: determining the independence among equipments according to sensitivity;

Creating module 6: selecting a power system state from the state set, and creating an independent adjacency matrix of the power system state through the independence among the equipments.

Besides, as shown in FIG. 4, the device also includes:

Inputting and initializing module 7: inputting power system data, equipment reliability data and preset parameters, and initializing order of contingency.

Further, the preset parameters include: maximum contingency search order and sensitivity threshold of equipment independence.

Further, as shown in FIG. 5, determining module 5 includes:

Determining sub-module 51: if there exists a branch, which makes the sensitivity index of branch flow distribution to the impedance of each faulty device is greater than the independence sensitivity threshold of the device, the two equipments are dependent.

In practice, the above mentioned modules and sub-modules can be realized by the devices with operation functions such as single SCM and PC. The type and device of the equipments are not limited in this embodiment.

The device improves the precision of calculating reliability index and the efficiency of computation, reduces the complexity of calculating reliability index through inspection module 1, first acquisition module 2, second acquisition module 3, third acquisition module 4, determining module 5, creating module 6, inputting and initializing module 7.

### Embodiment 4

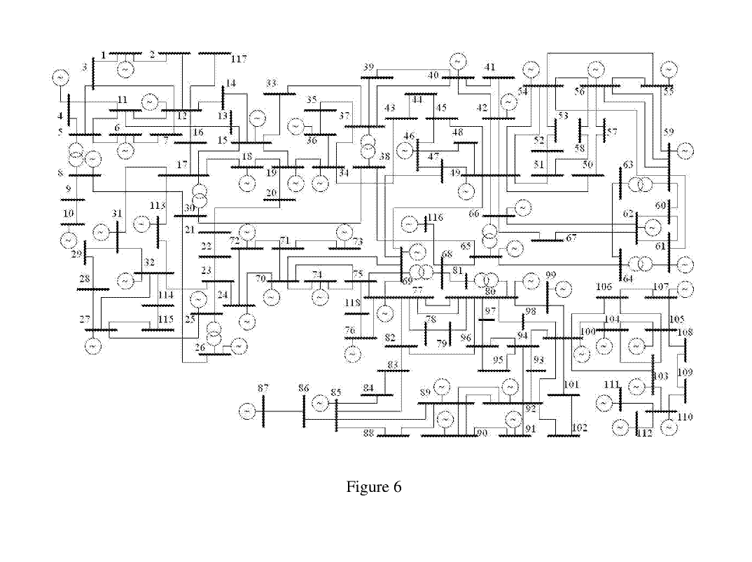

The implementing method and effects of the present invention will be further described by the following embodiment. The method of the present invention is firstly applied to the IEEE-118 system to test its performance. The topology of the IEEE-118 system is shown in FIG. 6. The test system contains 118 nodes, 54 generators, 186 branches, 54 PQ nodes and 64 load nodes. Total power generation and load demand are 9966 MW and 4242 MW, respectively. The MCS case is treated as a benchmark to evaluate the accuracy and efficiency of other cases.

Inputting the system data, setting the maximum contingency search order N_{CTG}=2 and device independent sensitivity threshold δₛ=0.02, initializing order of contingency states as 1; adding 0.01 p.u. impedance to each branch in sequence and calculating the power flow of each branch, and recording the power flow variation of each branch before and after the increase of impedance. The ratio of the power flow variation to 0.01 is the S_{PZ}, which represents branch impedance sensitivity to branch power flow of each branch. The rest of the steps refer to embodiments 1, 2, which are not described in detail in this embodiment.

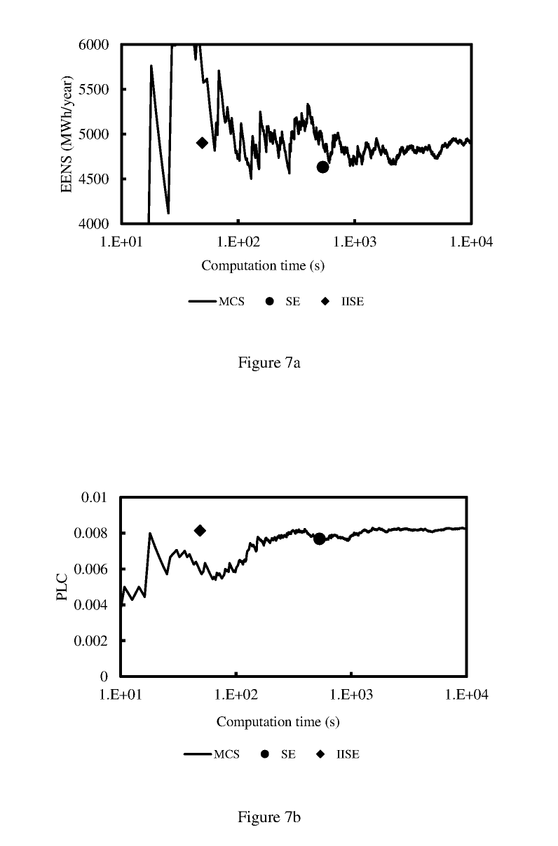

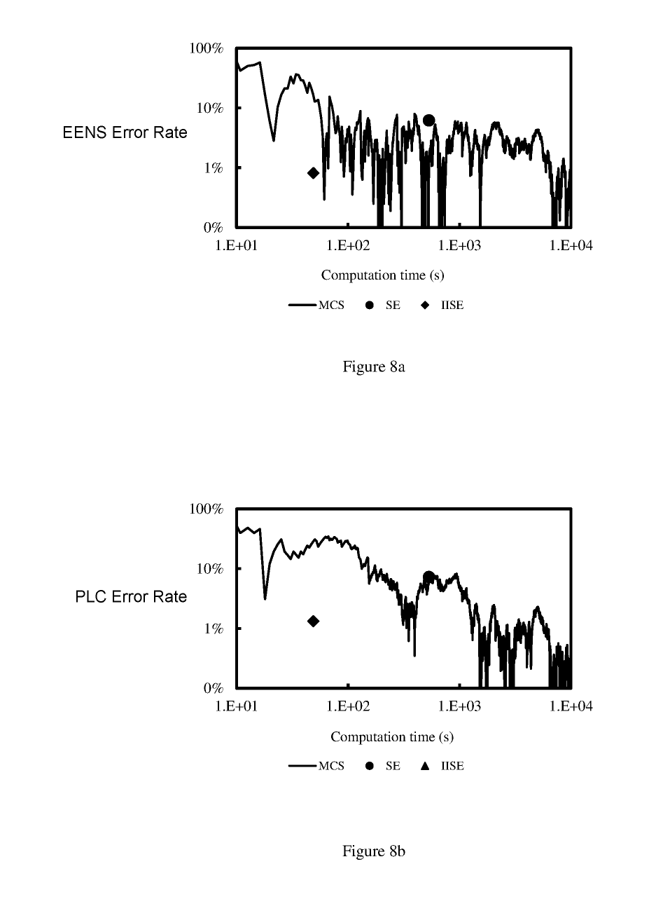

The indices of EENS and PLC for this system can be calculated as shown in table 1 according to the method mentioned before. Furthermore, the result of IISE is compared with MCS and SE. The N_{CTG} is altered to 2 while δₛ is altered to 10⁶ in each case. Considering the huge samples, MC will reach a result more accurate. So the MC result will be the criterion during comparison. The evaluation results are shown in table 1, FIG. 7a, FIGS. 7b, 8a and 8b.

TABLE I
EVALUATION RESULTS OF THREE ASSESSMENT
APPROACHES (IEEE-118)

| | EENS | EENS | PLC | PLC | CPU Time |
|---|---|---|---|---|---|
| Method | (MWh/y) | Error (%) | (10⁻³) | Error (%) | (s) |
| MCS | 4943 | — | 8.2560 | — | 17898 |
| SE | 4634 | 6.2357 | 7.6823 | 7.2863 | 531 |
| IISE | 4902 | 0.8182 | 8.1474 | 1.3157 | 48 |

As shown in Table I, indices (EENS and PLC) yielded by the MCS and the IISE are very close, whose relative errors are around 1%. (As shown in Table 1, the EENS error is 0.8182% and the PLC Error is 1.13157%.) However, for the traditional SE method, relative errors are over 6%. (As shown in Table 1, the EENS error is 6.2357% and the PLC Error is 7.2863%.) It can also be seen that the CPU time of the IISE is much less than the other two methods, indicating that the IISE is more efficient than other methods.

Convergence curves of the MCS and results of the IISE and SE are also shown in FIGS. 7a and 7b, indicating that the IISE is 10 times faster than the SE. FIG. 8a and FIG. 8b demonstrate the relative error convergence curve of the IISE and SE, respectively. Comparison between SE and IISE are also shown in FIGS. 7 and 8. As shown in FIG. 8a and FIG. 8b, the proposed IISE method is more accurate than SE, and cost only 1/10 CPU time. In addition, it can also be found that it costs about 10⁴ seconds before relative errors of the MCS drop to 1%. Such precision can also be reached by the IISE within 100 seconds, which is 100 times faster than the MCS.

In conclusion, IISE is more accurate and efficient than both SE and MCS.

### Embodiment 5

The implementing method and effects of the present invention will be further described by the following embodiment. The method of the present invention is firstly applied to the PEGASE power system to test its performance. The power system in this embodiment is a 1354-bus portion of European transmission system from PEGASE project (PEGASE) which involves 1354 buses, 1991 branches, 260 generators and 1094 load nodes. The total power generator capacity and load demand are 128739 MW and 73060 MW, respectively. The annual load curve is also introduced to this system. The MCS case is treated as a benchmark to evaluate the accuracy of other cases.

Inputting the system data, setting the maximum contingency search order N_{CTG}=1 and device independent sensitivity threshold δₛ=0.02, initializing order of contingency states as 1; adding 0.01 p.u. impedance to each branch in sequence and calculating the power flow of each branch, and recording the power flow variation of each branch before and after the increase of impedance. The ratio of the power flow variation to 0.01 is the S_{PZ}, which represents branch impedance sensitivity to branch power flow of each branch. The rest of the steps refer to embodiments 1, 2, which are not described in detail in this embodiment.

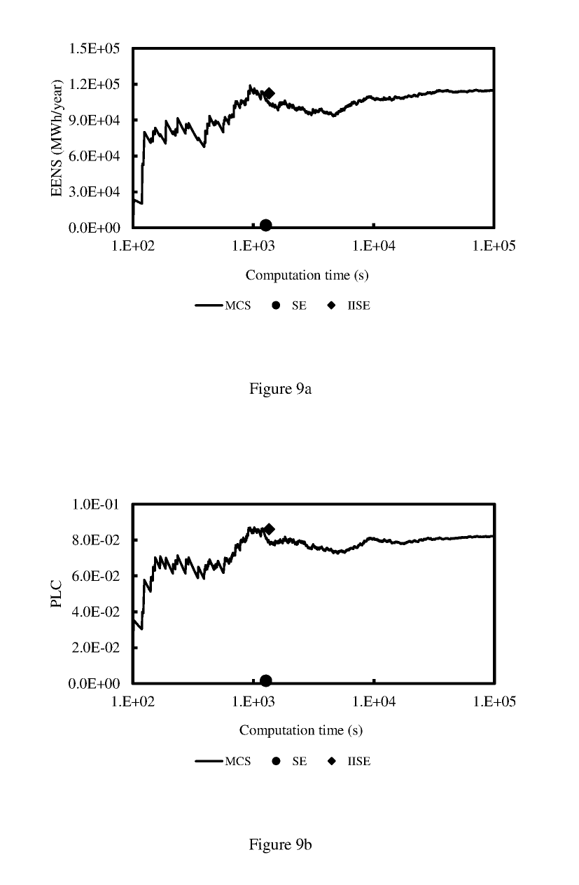

The indices of EENS and PLC for this system can be calculated as shown in table 2 according to the method mentioned before. The IISE, together with the SE and MCS, is applied to the PEGASE system to evaluate its reliability. N_{CTG} is set to 1 for both IISE and SE. Convergence criterion of the MCS is 10⁵ sampled system states. Results of the MCS are used as standards to calculate relative errors of other cases. Considering the huge samples, MC will reach a result more accurate. So the MC result will be the criterion during comparison. The evaluation results are shown in table 2, FIG. 9a, 9b, 10a, 10b.

TABLE II
RESULTS OF THREE ASSESSMENT APPROACHES (PEGASE)

| | EENS | EENS | PLC | PLC | CPU Time |
|---|---|---|---|---|---|
| Method | (MWh/y) | Error (%) | (10⁻³) | Error (%) | (s) |
| MCS | 114045 | — | 8.4010 | — | 119835 |
| SE | 2018 | 98.1514 | 0.1610 | 98.0834 | 1270 |
| IISE | 112382 | 1.4590 | 8.5828 | 2.1644 | 1350 |

As shown in Table II, indices (EENS and PLC) yielded by the MCS and the IISE are very close, whose relative errors are around 2% (as shown in Table II, the EENS error is 1.4590% and the PLC Error is 2.1644%.). However, for the SE, relative errors are over 98% (as shown in Table II, the EENS error is 98.1514% and the PLC error is 98.0834%.). It can also be seen that the CPU time of the IISE is much less than the other two methods, indicating that the IISE is more efficient than other methods.

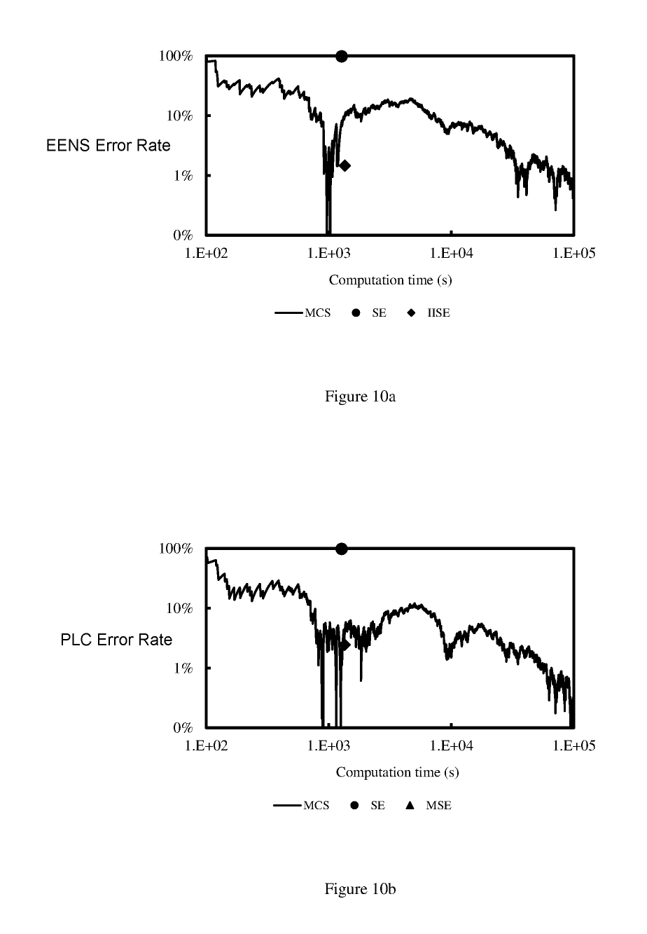

Convergence curves of the MCS and results of the IISE and SE are also shown in FIG. 9a, 9b. FIG. 10a, 10b demonstrated the relative error convergence curve, respectively. Comparison between SE and IISE that can also be shown in FIGS. 9 and 10. As shown in FIG. 10a and FIG. 10b, IISE method has better precision and efficiency than SE method. In addition, it can also be found that it costs about 3×10⁴ seconds before relative errors of the MCS drop to 2%. Such precision can be reached by the IISE within 1500 seconds, which is 0.05 times faster than the MCS.

In conclusion, IISE is more accurate and efficient than both SE and MCS.

It will be understood by those skilled in the art that the drawings are merely illustrative of a preferred embodiment, and that the serial No. of the embodiments of the present invention are for illustrative purpose only and are not indicative of ranking.

The foregoing specific implementations are merely illustrative but not limiting. A person of ordinary skill in the art may make any modifications, equivalent replacements and improvements under the teaching of the present invention without departing from the purpose of the present invention and the protection scope of the appended claims, and all the modifications, equivalent replacements and improvements shall fall into the protection scope of the present invention.

1-8. (canceled)

9. impact increments-based state enumeration reliability assessment approach, including the following steps:
inspecting the accessibility of all elements of the independent adjacency matrix by the breadth-first search method; if there is inaccessible element, the impact increment is zero and the power system state is reselected;
if there is no inaccessible element, evaluating the impact of the power system state under all load levels via optimal power flow algorithm, acquiring the impact expectations of power system state under different load levels, and then acquiring the impact increments of the power system state;
acquiring the reliability index of power system by impact increment when all the centralized power system states have been analyzed and the maximum number of contingency order has reached;
creating the adjacency matrix Dₛ:
Dₛ=[dᵢⱼ], i,j∈s;
where dᵢⱼ represents independence among branches; s represents power system state;
where, the term “accessibility” refers to the ability to get from one node V₁ to another node V₂ within an undirected connected graph determined by the adjacency matrix Dₛ;
calculating the impact increment ΔIₛ of the power system state s:
$$Δ {I}_{s} = {I}_{s} - {\sum }_{k = 1}^{{n}_{s}} {\sum }_{u ∈ {Ω}_{s}^{k}} Δ {I}_{u}$$
where, nₛ is the failure equipment number of the power system state s; Ωₛ^{k} is the k order subset of the system state s; u is a element of Ωₛ^{k}; ΔIᵤ is the load loss increment of u; Iₛ is the impact of system state s;
$$R = {\sum }_{k = 1}^{N} {\sum }_{s ∈ {Ω}_{A}^{k}} ( {Π}_{i ∈ s} {P}_{i} ) Δ {I}_{s}$$
where, R is the reliability indices; Pᵢ is the unavailability of equipment i; N is the total number of system equipment; Ω_{A}^{k} is the state set.

10. The impact increments-based state enumeration reliability assessment approach according to claim 9, wherein, before the step of accessibility” inspecting the accessibility of all elements of the independent adjacency matrix by the breadth-first search method”, the method also includes:
calculating the sensitivity of each equipment impedance to each branch power flow by perturbation method, and determining the independence of each equipment according to the sensitivity;
wherein, if there exists a branch, which makes the sensitivity index of branch flow distribution to the impedance of each faulty device is greater than the independence sensitivity threshold of the device, the two equipments are dependent;
selecting a power system state from a state set, and creating the independent adjacency matrix of the power system state.

11. The impact increments-based state enumeration reliability assessment approach according to claim 10, wherein, the method also comprises: inputting power system data, equipment reliability data and preset parameters, and initializing the order of contingency.

12. The impact increments-based state enumeration reliability assessment approach according to claim 11, the preset parameters include the maximum contingency search order and the sensitivity threshold of equipment independence.

13. An assessment device of the impact increments-based state enumeration reliability assessment approach according to any one of claims 9-12, wherein the device comprises:
inspection module: inspecting the accessibility of all elements of the independent adjacency matrix corresponding to the selected power system state by the breadth-first search method; if there is inaccessible element, the impact increment of the selected power system state is zero and the power system state is reselected;
first acquisition module: if there is no inaccessible elements, evaluating the impact of the power system state under all load levels via optimal power flow algorithm, acquiring the impact expectations of power system state under different load levels, and then acquiring the impact increments of the power system state;
second acquisition module: acquiring the reliability index of the power system by impact increment when all the centralized power system states have been analyzed and the maximum number of contingency order has been reached.

14. The impact increments-based state enumeration reliability assessment device according to claim 13, wherein the device of the present invention also includes:
third acquisition module: acquiring the sensitivity of each equipment impedance to the power flow of each branch through the perturbation method;
determining module: determining the independence among equipments according to the sensitivity;
wherein the determining module includes:
determining sub-module: if there exists a branch, which makes the sensitivity index of branch flow distribution to the impedance of each faulty device is greater than the independence sensitivity threshold of the device, the two components are dependent;
creating module: selecting a power system state from the state set and creating an independent adjacency matrix of the power system state through the independence among the equipments.

15. The impact increments-based state enumeration reliability assessment device according to claim 14, wherein the device also includes:
inputting and initializing module: inputting power system data, equipment reliability data and preset parameters, and initialize the order of contingency.

16. The impact increments-based state enumeration reliability assessment device according to claim 15, wherein, the preset parameters include the maximum contingency search order and the sensitivity threshold of equipment independence.
